(19) United States
(12) Patent Application Publication
(10) Pub. No.: US 2011/0260470 A1
(43) Pub. Date: Oct. 27, 2011

(54) Tribrid electric transportation system

(76) Inventor: William Ahmadi, Los Angeles, CA (US)

(21) Appl. No.: 12/799,358

(22) Filed: Apr. 23, 2010

(51) Int. Cl. F03D 9/02; H02J 7/02; H01L 31/042; H02K 7/18

(52) U.S. Cl. 290/1 R; 290/55; 320/109; 136/244; 180/65.21

(57) ABSTRACT

A tribrid electric transportation system including a dual generator wind turbine to produce wind energy, a solar panel mounted to the roof gathers a secondary source of solar energy, and a diesel fueled electric generator or fuel cell adds a third source of energy to an electric motor to propel the vehicle forward. The vehicle may consist of a plurality of vehicle types. A switching and control system allows the battery bank to be recharged when necessary, from any of the three primary sources of energy. The system is designed to have at least two energy sources directly power the electric motor, thereby preserving the battery pack as reserve energy when needed. An emergency backup charging unit may be available if the battery bank cannot be sufficiently recharged by the tribrid solar, wind and diesel generator or fuel cell systems. The invention takes advantage of this backup energy system to run more efficiently, under any condition, for longer distances and to preserve the battery bank for a much longer period of time.

This application claims priority of U.S. provisional patent serial number 61/134,295 filed on date Jul. 09, 2008; U.S. provisional patent serial number 61/210,167 filed on Mar. 16, 2009; U.S. patent Ser. No. 12/460,778 filed on Jul. 24, 2009 each of which is hereby incorporated by reference in its entirety.

### FIELD OF THE INVENTION

The present invention relates to a tribrid vehicle wherein specifically, an automobile possessing three separate methods of utilizing energy to power an electric motor.

### BACKGROUND INFORMATION

Prior Art

Alternative energy powered vehicles are well known and consists of a plurality of technologies, such as fuel cells, hydrogen power, solar, wind and hybrid systems usually consisting of a combustion engine and an electric engine combination.

The need for an alternative fuel and power systems is immense as fossil fuels deplete and concerns about pollution continue to rise.

The continued release of hydrocarbon gases into the atmosphere has begun to affect the worlds climate in adverse ways, and with continued growth in Asia the problem and scope will only accelerate this problem. It is now well known that alternative methods of energy use and production methods must be incorporated into everyday living.

Currently, in alternative vehicle technology most attention has gone into the development of hybrid technologies which typically use an internal combustion engine along with an electric motor. U.S. Pat. No. 7,383,902 Matsuzaki, et al. Jun. 10, 2008 teaches that in a motor directly driven from the output of a generator, the motor must be controlled so that the maximum torque is output from the electric motor when the vehicle is started and that the torque of the electric motor decreases as the vehicle speed increases. Also more improvement is needed in the area whereby the running performance of a four wheel driven vehicle is improved further to bring it near what is achieved in a two wheel driven motor. It is noted that the generator output control creates a large generator torque given to the internal combustion engine, whereby said torque load exceeds the permissible torque load of an internal combustion engine which causes an overload of the internal combustion engine causing the engine to stall.

Thus a generator control is included to maintain the generator torque within an acceptable range so that the engine does not stall. In addition a generator driven by the internal combustion engine drives one pair of the wheels, front or rear, whereas an electric motor driven by the output of a generator drives the other set of wheels.

However the difficulty with hybrid engines, in general, remain. Namely, the need for two different engines mounted in one vehicle. Multiple gears and drive shafts, universal joints, transaxle, constant velocity joints and geared differential or rotating axle shafts are typically found in the hybrid car. This twofold system has kept costs relatively high and creates difficulty with servicing such vehicles, a prime reason why the hybrid car has not found a larger market.

Another form of technology is noted in U.S. Pat. No. 7,493,974 Boncodin Feb. 24, 2009 teaches a solar powered thermoelectric vehicle including a fiber optics bundle heat collector/conductor. Thermoelectric chips power a plurality of thermoelectric powered generators with the use of a heat sink comprised of either carbon graphite, cylindral blocks, metals, ceramics or tiles. The invention includes two heat producing motors which supply the thermoelectric generators with heat when sunlight is poor

Hydrogen fuel cell technology is yet another area that has received much attention in relation to powering vehicles. U.S. Pat. No. 7,172,826 Nomoto Feb. 26, 2007 and U.S. Pat. No. 6,638,493 Anderson et al. Oct. 28, 2003 teaches that the use of hydrogen causes moisture to form at a cathode electrode caused by the chemical reaction of hydrogen and oxygen. The moisture may condense into a liquid and overflow into an oxygen passage, thereby obstructing the diffusion of oxygen gas, which in turn inhibits the effective reaction between the hydrogen and oxygen.

Another concern taught by Anderson is, with hydrogen is the formation of aluminum oxide compounds. Aluminum reacts with water at preferably higher temperatures. Hydrogen is split from oxygen where the hydrogen is released as a gas and the oxygen binds with the aluminum plates to form aluminum oxide compounds which forms a film which covers the surface of the aluminum. This film must be regularly cleaned away from the surface of the aluminum to keep the chemical reaction going. Also ambient temperatures do not allow the reaction to take place.

Other concerns regarding hydrogen are in the storage of hydrogen and the safety of a vehicle should it be involved in an accident.

Wind powered vehicles have also been around for some time now. U.S. Pat. No. 3,876,925 Stoeckert Apr. 8, 1975 discloses a wind turbine driven generator wherein the turbine is mounted to the roof of the car, and is used to recharge the systems batteries of an electric vehicle whether the car is moving or not. Other relevant prior art in this field includes U.S. Pat. Nos.: 3,374,849, 3,444,946, 3,359,479, 3,621,930, 6,138,781 and 6,838,782 each of which represents a wind turbine powered generator system.

As noted in U.S. Pat. No. 3,876,925, the greater wind velocity will be more generally toward the front end. All noted prior art mounts the wind turbine atop the roof whereas the present invention utilizes the front end grill to mount a wind turbine.

U.S. Pat. No. 4,168,759 Hull deceased et al. Sep. 25, 1979 discloses a specially designed front end, windshield and roof to act as a scoop to draw airflow into its air chamber to its impeller blades, however this design seriously impedes a more viable aerodynamic shape and air flow where the scoop shape may collect wind yet also may cause undesired friction and resistance.

Lastly, ethanol has been looked into as an alternative fuel, however currently ethanol is not economically competitive with gasoline. Mass use of ethanol would require immense costs for infrastructure improvements to the entire nations fuel production and delivery systems, and a revision or duplication of systems for vehicle manufacturers, distribution and repair systems if ethanol is to be used on a large scale basis.

While the existing systems achieve a varying degree of success, a need exists for improvements in this technology. None of the prior art mentioned above, either singly or in combination, describes the present invention as is claimed herein.

### SUMMARY OF THE INVENTION

The present invention includes improvements over singular alternative energy systems such as solar, wind, hybrid or ethanol based systems. The improvements seek to combine a plurality of energy systems to provide backup generating power should one or more systems run below the required torque needed to propel a vehicle.

The present invention utilizes an improved wind turbine system to run a generator by placing the turbine in the front grill section, the roof, a specialized bumper or a combination thereof.

The wind turbine consist of a shaft less center whereby two generators are connected to said turbine by miniature shafts, in the preferred embodiment, or as a full central shaft located at either generator. The turbine blades are specially designed to operate under low and high wind velocities.

In conjunction with the wind power, a solar panel is placed on the roof top of the vehicle to increase the charging level of the vehicles batteries.

A fuel cell is combined, in one embodiment with the above to create a tri-brid system whereby the vehicle will always store enough energy for easy propulsion. A control unit is included to insure against over charging the generators, to protect against the stalling of the engine. In addition an auto-synchronizer module acts to automatically synchronize the generators.

The present invention includes head lights, tail light and interior lighting composed of a circular ring of jumbo LED lights mounted within the light housings, where less energy is used to power said LED members.

The preferred embodiment combines a dual generator wind turbine, with a roof surface solar panel, combined with a diesel fueled electric generator tribrid system managed through a charge controller unit. Said charge controller directs the flow of current from each system directly either to the battery bank or to the electric motor as the need arises. The solar panel is also directly connected to the vehicles air conditioning unit, which in turn is also connected to the battery bank should a need for more power occurs.

The electric engine can also be charged via an AC power charger at available charging stations.

Accordingly, it is a principal object of the present invention to provide an improved tribrid system which utilizes a minimum of three power sources to power a vehicle.

It is another object of the present invention to incorporate an improved wind driven electricity generating system, among its other systems, to improve the efficiency of wind power generated by the dual generator wind turbine.

Still another object of the present invention is to incorporate a tri-brid system of energy production to more efficiently power a vehicle, whereby its generators constantly recharges its batteries even if one system operates at a low capacity, for instance, on a cloudy day the solar panel will collect less sun energy, yet the overall system provides enough energy and secondary energy to effectively power the vehicle as desired.

Or the vehicle may operate on wind power, diesel generator or fuel cell power with the solar power acting as an emergency back up source.

Still another object of the present invention is to provide an efficient tri-brid energy system composed of sensors that detect the charge level of the batteries. Should the system exceed the maximum level allowed for, the sensor will act to shut off any additional power system(s) not needed at the time to effectively propel the vehicle.

Still another object of the present invention is to provide an automatic switching system whereby ideally the wind and solar power directly powers the electric engine when the system sensors detect a fully charged battery.

Unlike present hybrid systems, the tribrid system does not require two or more separate systems to function. A system of two power trains are needed to run the dual systems of the hybrid, where as in traditional internal combustion engines the tribrid system requires only one electric energy drive train and system.

Drawings

### BRIEF DESCRIPTION OF THE DRAWINGS

The following description should explain the present invention in detail on the basis of drawings. However, it is understood that the invention is not limited to the precise arrangements and instrumentalities shown.

FIG. 1 is a side view of tribrid vehicle

FIG. 2 is a top cut out view of tribrid vehicle

FIG. 3 is a front view, without wind turbine, of tribrid vehicle

FIG. 4 is a front view, with wind turbine, of tribrid vehicle.

FIG. 5 is a top internal view of the major parts of tribrid vehicle

### DETAILED DESCRIPTION OF A PREFERRED EMBODIMENT OF THE DRAWINGS

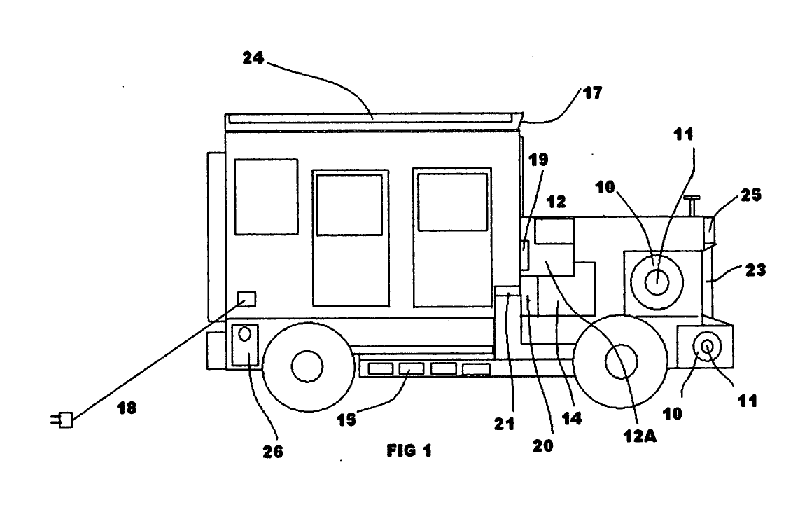

FIG. 1 shows a side view of the tribrid vehicle of an embodiment of the present invention. An electric motor 14 mounted along the center of the chassis back deep into the engine well behind the front axis or axle of the vehicle. Said vehicle further comprises a fuel cell 12 mounted alongside the electric motor 14, operating at 120 V-150 V, also deep in the engine well behind the front axis or axle with sufficient spacing for ventilation of said electric motor and diesel generator 12A. The diesel generator 12A is capable of supplying power directly to the battery bank 15 or directly to the electric motor 14.

Said vehicle further comprises a wind turbine 10 linked to two generators 11 by shafts at both ends which attach to said generator 11 on either side, the opposing end attached to said turbine 10, however the main body of the turbine 10 is free of the traditional single through shaft, in the preferred embodiment, that runs from one generator stator to the other. Said turbine 10 blades placed in a horizontal position, form double right angular bends in the preferred embodiment.

Said vehicle further comprises a front end air intake grill 16, located where the radiator of an internal combustion engine is mounted, comprised of a plurality of horizontal chrome plated metallic dividers spaced approximately two inches apart from one another, to allow maximum airflow to reach said wind turbine 10.

Said turbine 10 is placed back from said air intake grill 16 creating a wind intake chamber 24 allowing for the wind to collect in an area before reaching said wind turbine 10

Said vehicle further comprises a solar module panel 13 lying parallel to the roof with a space between said solar panel 13 and the roof created by a plurality of vertically placed rooftop air intake grill 17 members formed identically as the air intake grill 16 members, whereby the base of said solar panel 13 is allowed to vent and cool by the on rushing winds.

Said electric motor 14, wind turbine 10, solar panel 13, battery bank 15, and diesel generator 12A, are directly wired to said charge controller unit 19 to control switching to said battery bank 15, and electric motor 14, from all stated energy sources. Charge controller unit 19 is placed behind a firewall protective covering in the rear of the engine well aside of said electric motor 14

Said vehicle further comprises a plug in outlet 18 on the rear side of the vehicle placed where a traditional internal combustion engine gasoline cover and cap are placed. Said plug in outlet 18 features a traditional cover as the aforementioned gas cap has. Said plug in outlet 18 is used at electric car charging stations when said battery bank 15 is low and in need of a recharge, in instances where said vehicles wind turbine 10 and or solar panel 13 or diesel generator 12A cannot fully charge said battery bank 15.

Said vehicle also further comprises LED head lights 25 placed in front of the vehicle on both sides of said front end intake grill 16. Said vehicle also comprises LED tail lights and interior lighting.

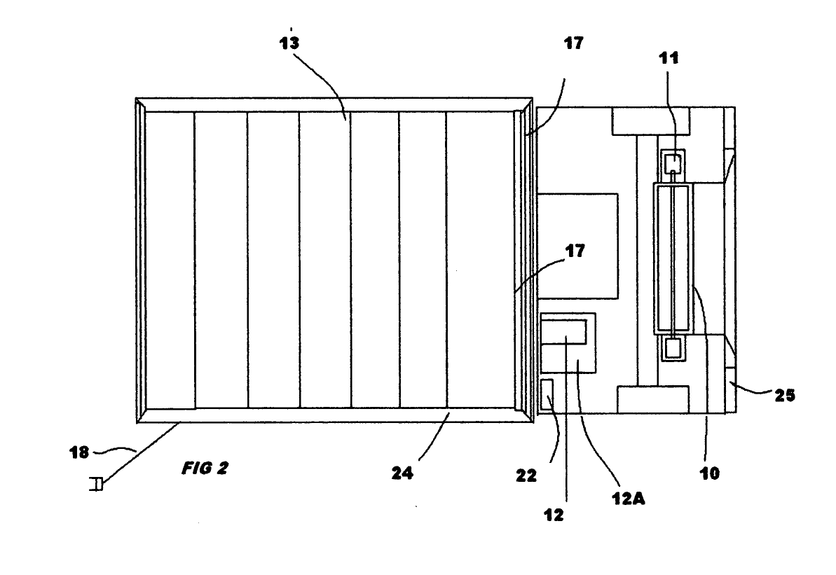

As shown in FIG. 2 thereof, a wind turbine 10 is fixedly mounted on two mini shafts, above and along the front axle or axis of the vehicle, thereby attached to two separate generators 11, which are either bolted down to the interior body frame, or secured to said air intake grill 16 within the rear of the wind intake chamber 23. Said wind intake chamber 23 consolidates the airflow leading into the front end air intake grill 16.

Located in the rear of the engine well relatively placed in the center is the electric motor 14, where a diesel generator 12A resides alongside said electric motor 14

Atop said vehicle roof, aligned along both front and rear ends, are located the rooftop air intake grill 17 forming a specialized ventilation system for said raised rooftop solar module panels, 13 the sides of which are bounded by a solar enclosure 24 identically matched with the vehicles body frame and color. The solar enclosure 24 locks the solar panel 13 into place, whereby its outer glass surface allows for the intake of solar energy which is transferred from said solar panels 13 to the controller unit 19 which directs the energy to either the battery bank 15, electric motor 14, or air conditioning unit, as needed.

Located in front of the vehicle on both sides of said air intake grill 16, are LED headlights 25. Said vehicle also comprises LED tail lights and LED interior lighting.

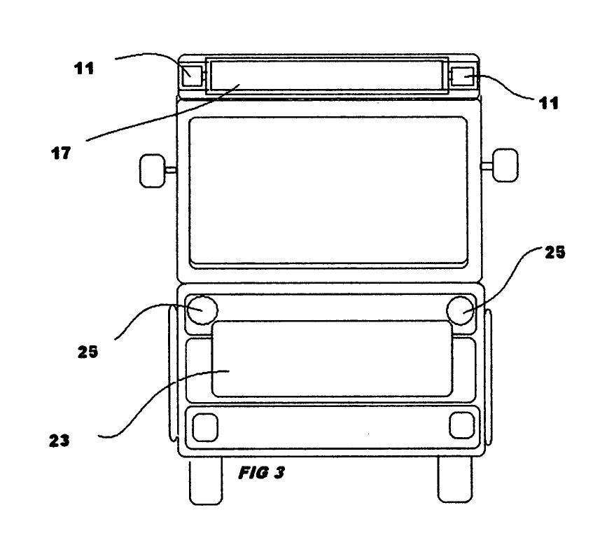

FIG. 3 shows a front view of the present invention. A raised solar panel 13 adorns the roof of said vehicle spaced on both front and rear sides by a rooftop air intake grill 17 consisting of thin metallic planer surfaced blades, spaced appreciably apart from one another creating larger channels for incoming wind to enter and cool the undersurface of the solar panel 13. In the present embodiment of the invention, the frame and size of the vehicle is that of a truck, SUV, or van. Other embodiments of course include the car but also include larger trucks as well. A solar enclosure 24 is built into the external roof framing melding with the design of a plurality of models, in the process fully housing the roof top solar module panel 13 Placed on both left and right along a horizontal axis are two sides above said front end air intake grill 16, are two LED headlights 25. The rear lights and the interior lights are also LED illuminated. Said LED headlights 25 form a circular pattern by means of a plurality of jumbo LED lights placed within a housing of metallic materials and enclosed by a glass or plastic transparent, or translucent surface in a plurality of shapes forming a lens.

Beneath and within said LED headlights 25 is a rectangular shaped front end air intake grill 16 of chrome plated metals aligned vertically, consisting of a plurality of horizontally aligned grill blades. The spacing between the blades of the front end air intake grill are exaggerated to allow for greater wind force within the wind turbines 10 chamber.

In this embodiment of the present invention the vehicles bumper is customized to include an air duct opening composed of a central rectangular shaped opening housing a wind turbine 10. With a square shaped cutaway on both sides of the wind turbine 10.

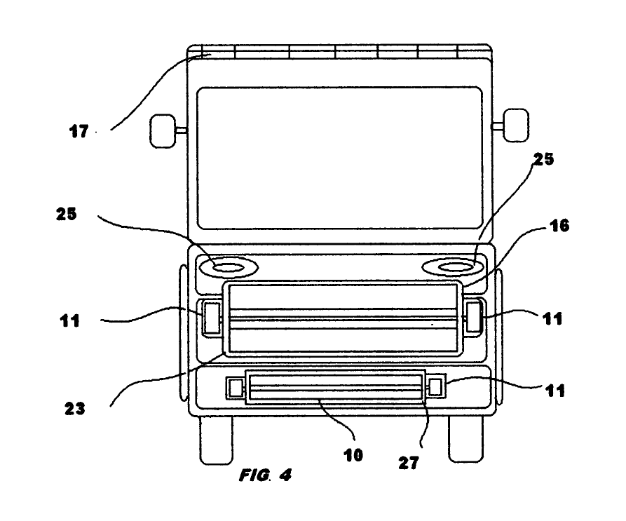

FIG. 4 illustrates the same angle as does FIG. 3, however with these noted differences to further describe different details of said vehicle. The roof further illustrates the rooftop air intake grill 17 which ventilates said solar panels 13. In other embodiments this rooftop air intake grill 17 allows air to flow underneath said solar panels 13 and power said wind turbines 10 located atop said vehicle.

The cutaway section of the front grill reveals the dual generator 11 wind turbine 10. A special plurality of blades are attached to said wind turbine 10, in the preferred embodiment as two right angled bends in the turbine blade, allowing minimal negative resistance against the wind. In other embodiments the turbine blades may come in a plurality of shapes, such as, but not limited to, S-blades and C-blades.

Beneath the grill, mounted within the bumper lies an additional wind turbine 10 attached to a pair of generators 11. Said generators 11 are synchronized by an auto-synchronizer module.

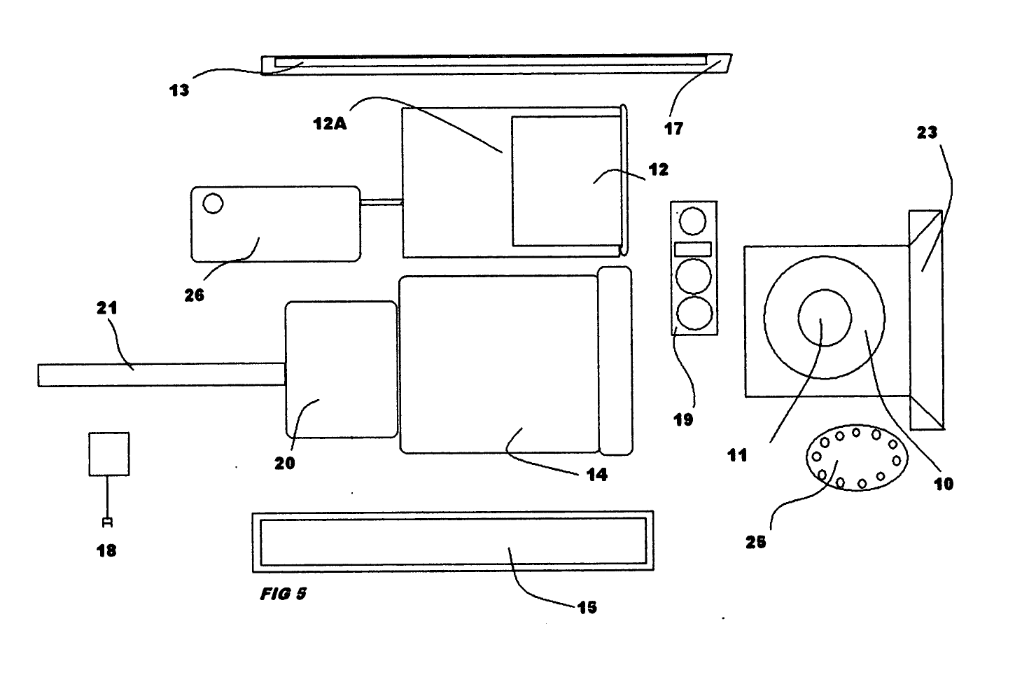

FIG. 5 refers to a top view layout of the main internal parts of the tribrid vehicle. At the extreme ends of the front frame lie a plurality of LED headlights 25 set within a housing unit in a circular shape about the housing. Between said LED headlights 25 rests the front end air intake grill 16 whereby air enters the wind intake chamber 23 before reaching and powering said turbine 10 blades. A charge controller unit 19 is wired to said wine turbine 10, battery bank 15, diesel electric generator 12A, and electric motor 14 wherein said charge controller 19 regulates the flow of current to said battery bank 15, and said electric motor 14 form the tribrid vehicles energy sources.

The solar panel 13 enclosed by a rooftop air intake grill 17 is atop a central location of the vehicle along the rooftop.

Deep within the engine well lies said diesel generator 12A is fueled by a diesel fuel tank 26. Said electric motor 14, is attached to a gearbox transmission 20, which in turn powers the drive shaft 21 which in turn drives the axles attached to the vehicles wheels.

Below the center said tribrid vehicle lies the battery bank 15 of lithium ion, in a preferred embodiment.

FIG. 5 also illustrates the plug in outlet 18′ located on a rear side panel of the vehicle. And also illustrates an air conditioner unit wired directly to said solar panel 13, in addition to a light switch wired both to the battery bank 15 to receive energy, and the LED headlights 25 which receive the energy.

### LIST OF DRAWING REFERENCES

10. Wind Turbine

11. Generator

12. Hydrogen fuel cell

12A. Diesel fueled electric generator

13. Solar module panel

14. Electric motor

15. Battery bank

16. Front end air intake grill

17. Rooftop air intake grill

18. Plug in outlet

19. Charge control unit

20. Gear box

21. Drive shaft

22. charge controller

23. Wind intake chamber

24. Solar enclosure

25. LED headlights

26. Diesel fuel tank

27. Bumper air intake grill.

CONCLUSION, RAMIFICATIONS AND SCOPE

While the present invention has been defined in the preferred embodiment , it is understood that numerous modifications and variations of this embodiment will occur to those with ordinary skill in the art. All such modifications and variations shall be deemed to fall within the scope and spirit of the present invention as defined by the appended claims to the invention.

I claim:

1. A tri-brid electric transportation system having at least three means of power generation comprising a dual generator wind turbine mounted in the grill, roof or bumper of said vehicle which produces electrical power from wind energy, and:
A ventilated grill on the front end and roof section of said vehicle.
A fuel cell which produces electrical power from chemical reactions within the fuel cell or a diesel electric generator.
A solar panel placed atop said vehicles roof to collect solar energy.
An electric motor whose output is transferred directly to the wheels.
A plurality of batteries to store energy captured by solar, wind and fuel cell sources.
A control unit for the controlling the output of the generators.
A diesel electric engine which produces electric power from the combustion of diesel fuel.
A plug in unit adorns the vehicles side.
An auto-synchronizer module is mounted in said vehicle
A set of LED headlights, tail lights, and internal lights

2. A tribird electric transportation system according to claim 1, wherein said dual generator wind turbine consists of a plurality of blades and blade shapes or types.

3. A tribrid electric transportation system according to claim 2, wherein said dual generator wind turbine preferred embodiment forms a near trapezoidal dimension of a plurality of right angular bends.

4. A tribrid electric transportation system according to claim 2, wherein said dual generator wind turbine consists of a shaft less center where a plurality of turbine blades are attached to said shaft less center by means of a plurality of screws or rib bits.

5. A tribrid electric transportation system according to claim 1, wherein said dual generator wind turbines are mounted in a plurality of locations, such as in the grill, on the front or rear of the roof, or within the bumper.

6. A tribrid electric transportation system according to claim 1, wherein said dual generator wind turbines produce energy that may be stored within the batteries or may be sent directly to the electric motor for propulsion of the vehicle or may be directed by means of a charge controller unit to power auxiliary electric systems, such as, but not limited to, steering, braking, wipers, lights, and radio, if needed.

7. A tribrid electric transportation system according to claim 1, wherein said front end grill is comprised of a chrome plated metal, aligned vertically or horizontally at least two and one half inches apart from each other, in a planar blade like shape.

8. A tribrid electric transportation system according to claim 7, wherein said front end grill has an extended entry chamber for air to forcefully collect and power the turbine, which in turn power said generators.

9. A tribrid electric transportation system according to claim 1, wherein said roof section is adorned by a solar panel, lying parallel to said roof. Said solar panel being attached to said roof by means of a rooftop grill separating said solar panel from said roof.

10. A tribrid electric system according to claim 9, wherein said rooftop grill consists of a raised solar panel three or more inches above the surface of said roof , attached to a plurality of vertically spaced blades or bars along the diameter of said roof said ventilation blades are spaced at least two and one half inches apart.

11. A tribrid electric system according to claim 10, wherein said rooftop grills raised solar panel allows wind to travel through the grill duct at the base of the solar panel allowing the cooling and ventilation needed by said solar panel to operate optimally.

12. A tribrid electric system according to claim 1, wherein said diesel generator or fuel cell directly recharges the batteries when said batteries fall below a preset level of charge. Said diesel generator or fuel cell acts as a back up power system to the wind and solar powered electric motor

13. A tribrid electric system according to claim 1, wherein said solar panel is placed parallel to said roof, placed a few inches above thereof. Said rooftop grill attached around the perimeter of said solar panel allowing for cooling air to circulate beneath said solar panel. Said solar panel collects energy to charge the batteries and power the air conditioning unit, or act in tandem with the diesel generator or fuel cell, and wind turbine generators to directly power said vehicle when needed.

14. A tribrid electric system according to claim 5, wherein said rear rooftop generator wind turbine receives airflow to power its turbine blades through the solar vents in the rooftop grill.

15. A tribrid electric system according to claim 1, wherein said solar panel is topped with a transparent top of plastic or glass.

16. A tribrid electric system according to claim 1, wherein said solar panels output is directed to a charge controller unit to manage the flow of energy needed from said solar panel to the batteries and auxiliary systems.

17. A tribrid electric system according to claim 13, wherein said solar panel is raised by an enclosure, on either side, that is blended into the side surface of the vehicle.

18. A tribrid electric system according to claim 1, wherein said electric motor is directly powered by the diesel generator or fuel cell, if needed, when solar and wind energy fall below a needed level to operate said motor efficiently, and can receive additional power if needed from the batteries. Said electric motor powers the transmission which then turns the wheels of the vehicle by means of a drive shaft.

19. A tribrid electric system according to claim 1, wherein said battery bank can act as a direct power to drive the electric motor or through a control member simply store energy for when it is needed by the vehicle.

20. A tribrid electric system according to claim 19, wherein said battery banks preferred state of use is as a backup source of power to the solar and wind systems directly powering said electric motor.

21. A tribrid electric system according to claim 1, wherein said control unit controls said generators output to prevent electric motor overloads.

22. A tribrid electric system according to claim 21, wherein said control unit is attached to all said means of electrical production in said vehicle and acts to govern which system or systems will power the battery bank and which system or systems will directly power said electric motor at any given time.

23. A tribrid electric system according to claim 1, wherein said diesel electric engine directly powers the electric motor in a preferred embodiment, if needed, when solar and wind energy fall below a needed level to operate said motor efficiently, and by means of a charge controller unit, can also provide current to directly to recharge the battery bank if it falls below a certain level.

24. A tribrid electric system according to claim 1, wherein said plug in outlet lies on one side of the vehicle placed where a gas cap is normally placed on an internally combustion engine, and allows for the recharging of the vehicles said battery bank, if and when other sources of energy cannot charge the battery bank if it falls below a certain level.

25. A tribrid electric system according to claim 1, wherein said auto-synchronizer module can automatically synchronize the dual generators of the wind turbine.

26. A tribrid electric system according to claim 1, wherein said headlights, taillights and interior lights consists of a plurality of jumbo LED lights placed about the housing in a circular fashion.
